(19) United States
(12) Patent Application Publication
(10) Pub. No.: US 2023/0412355 A1
(43) Pub. Date: Dec. 21, 2023

(54) DATA RECEIVING APPARATUS

(71) Applicant: SONY SEMICONDUCTOR SOLUTIONS CORPORATION, KANAGAWA (JP)

(72) Inventors: NAOTO YANASE, KANAGAWA (JP); KAZUTOSHI DOUKE, KANAGAWA (JP); YASUHIRO WATANABE, KANAGAWA (JP); RYO TAKAHASHI, KANAGAWA (JP)

(21) Appl. No.: 18/252,161

(22) PCT Filed: Oct. 14, 2021
(86) PCT No.: PCT/JP2021/038046

§ 371 Date: May 8, 2023

(30) Foreign Application Priority Data
Nov. 16, 2020 (JP) 2020-190021

(51) Int. Cl. H04L 7/02; H04L 7/00; H03K 5/26

(52) U.S. Cl. CPC H04L 7/02; H04L 7/0079; H03K 5/26; H03K 2005/00286

(57) ABSTRACT

A data receiving apparatus of the present disclosure includes a first phase adjustment circuit and a second phase adjustment circuit. The first phase adjustment circuit performs a phase adjustment between multiple data signals received via multiple data signal lines. The second phase adjustment circuit performs a phase adjustment of a clock signal received via a clock signal line with respect to the multiple data signals after the phase adjustment between the multiple data signals is performed by the first phase adjustment circuit.

### TECHNICAL FIELD

The present disclosure relate to a data receiving apparatus that receives a clock signal and multiple data signals.

### BACKGROUND ART

Examples of high-speed interface standards for mobile devices and camera devices include a C-PHY standard and a D-PHY standard developed by Mobile Industry Processor Interface (MIPI) Alliance. For example, the D-PHY standard involves one transmission path (clock lane) for transmitting a clock signal and one or more transmission paths (data lanes) for transmitting data signals. For such interfaces, a technique is proposed in which a delay circuit is provided, and a skew between the clock signal and the data signal is eliminated by delaying one of the clock signal and the data signal with respect to the other signal (refer to PTL 1).

### CITATION LIST

### Patent Literature

PTL 1: Japanese Unexamined Patent Application Publication No. 2018-29269

### SUMMARY OF THE INVENTION

For the technique described above, in a case where multiple data lanes are provided, a delay circuit is provided between each of the data lanes and a clock lane, and a phase adjustment is performed between each data signal and a clock signal. Thus, a circuit scale and power consumption inevitably increase as the number of data lanes increases.

It is desirable to provide a data receiving apparatus that makes it possible to perform a phase adjustment between multiple data signals and a clock signal while reducing a circuit scale and power consumption.

A data receiving apparatus according to one embodiment of the present disclosure includes a first phase adjustment circuit and a second phase adjustment circuit. The first phase adjustment circuit performs a phase adjustment between multiple data signals received via multiple data signal lines. The second phase adjustment circuit performs a phase adjustment of a clock signal received via a clock signal line with respect to the multiple data signals after the phase adjustment between the multiple data signals is performed by the first phase adjustment circuit.

The data receiving apparatus according to one embodiment of the present disclosure performs the phase adjustment of the clock signal with respect to the multiple data signals after the phase adjustment between the multiple data signals is performed by the first phase adjustment circuit.

### BRIEF DESCRIPTION OF DRAWINGS

FIG. 1 is a timing chart schematically illustrating an example of an operation of a data receiving apparatus according to a comparative example.

FIG. 2 is a block diagram schematically illustrating a configuration example of a communication system to which a data receiving apparatus according to a first embodiment of the present disclosure is applied.

FIG. 3 is a circuit diagram schematically illustrating a configuration example of the data receiving apparatus according to the first embodiment.

FIG. 4 is a timing chart schematically illustrating an example of an operation of the data receiving apparatus according to the first embodiment.

FIG. 5 is a circuit diagram schematically illustrating a configuration example of a data receiving apparatus according to a second embodiment.

FIG. 6 is a timing chart schematically illustrating an example of an operation of the data receiving apparatus according to the second embodiment.

### MODES FOR CARRYING OUT THE INVENTION

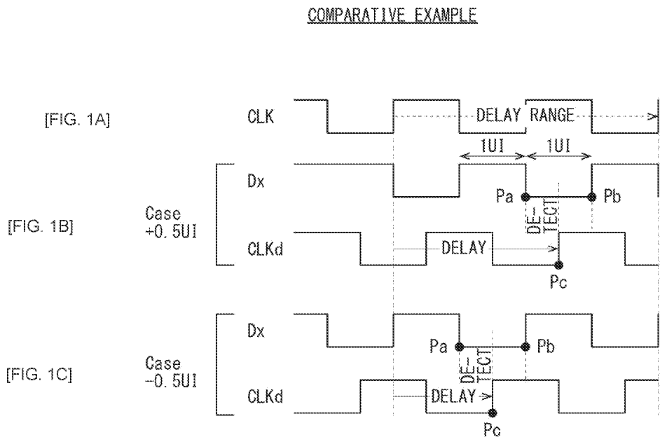

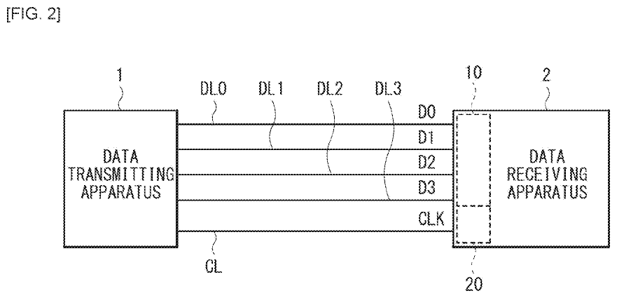

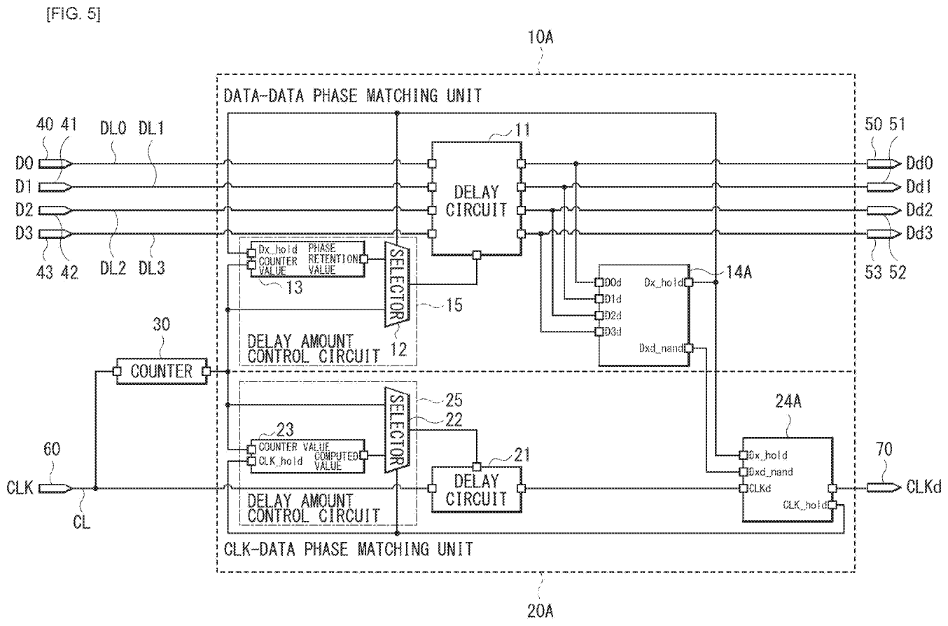

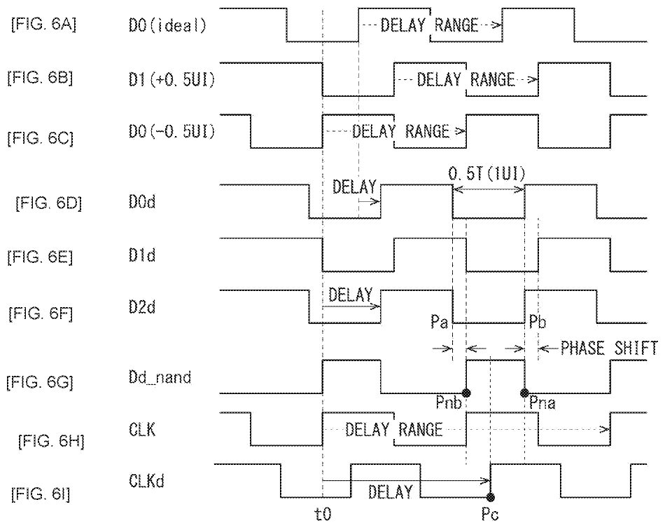

In the following, some embodiments of the present disclosure are described in detail with reference to the drawings. It is to be noted that the description is given in the following order.
0. Comparative Example (FIG. 1)
1. First Embodiment (FIGS. 2 to 4)
   1.1 Configuration
   1.2 Operation
   1.3 Effects
2. Second Embodiment (FIGS. 5 to 6)
   2.1 Configuration
   2.2 Operation
   2.3 Effects
3. Other Embodiments

### 0. Comparative Example

### Outline and Problems of Operation of Data Receiving Apparatus According to Comparative Example

FIG. 1 is a timing chart schematically illustrating an example of an operation of a data receiving apparatus according to a comparative example.

In a technique described in, for example, PTL 1 (Japanese Unexamined Patent Application Publication No. 2018-29269) as a comparative example, a delay circuit is provided between a data lane and a clock lane and a phase adjustment is performed between a data signal and a clock signal CLK.

FIG. 1 illustrates an example of a phase condition between a data signal Dx and the clock signal CLK in a case where the phase adjustment is performed between the data signal and the clock signal CLK using the technique described in PTL 1 as the comparative example. FIG. 1(A) illustrates an example of the phase of the clock signal CLK received by the data receiving apparatus. Ideally, it is desirable to perform the phase adjustment so that the clock signal CLK has a rising edge or a falling edge substantially at the center of the period of one unit interval (UI), which is the unit time of data transfer of the data signal Dx.

FIG. 1(B) illustrates an example of a phase adjustment to be performed in a case where the phase of the data signal Dx is advanced by 0.5UI from an ideal phase condition with respect to the clock signal CLK. FIG. 1(C) illustrates an example of a phase adjustment to be performed in a case where the phase of the data signal Dx is delayed by 0.5UI from the ideal phase condition with respect to the clock signal CLK. For example, a rising edge Pd and a falling edge Pa of the data signal Dx within 1UI are detected, and the clock signal CLK is delayed to generate a delay clock signal CLKd having a rising edge Pc at an intermediate position between the rising edge Pb and the falling edge Pa.

### Problems of Data Receiving Apparatus According to Comparative Example

The technique described in PTL 1 is a phase adjustment technique for a combination of one clock signal CLK and one data signal Dx. In the technique described in PTL 1, the rising edge Pb and the falling edge Pa of the data signal Dx are detected while the amount of delay of the clock signal CLK is changed, and the result of detection is stored. Thereafter, a value indicating the result of detection is calculated to determine an optimal amount of delay of the clock signal CLK. Thus, a variable amount of delay of the clock signal CLK needs a scale of about 1.5 to 2 cycles of the cycle of the data signal Dx. Because the amount of delay actually needed to perform the phase adjustment is up to 1 cycle, 0.5 to 1 cycle is redundant.

Further, as for the technique described in PTL 1, which is a phase adjustment technique for a combination of one clock signal CLK and one data signal Dx, increasing the number of data lanes involves multiple delay circuits corresponding to the number of data lanes. In addition, as for the technique described in PTL 1, which is a technique of a phase adjustment between one clock signal CLK and one data signal Dx, if there are multiple data lanes, the phase adjustment between multiple data signals needs to be performed. This results in a larger circuit area and a larger power consumption.

### First Embodiment

### 1.1 Configuration

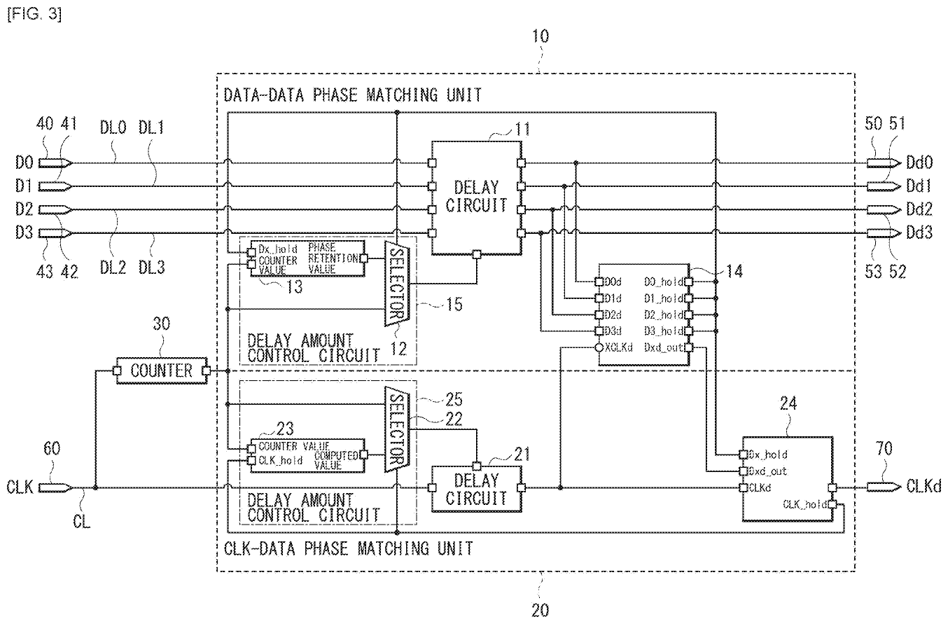

FIG. 2 schematically illustrates a configuration example of a communication system to which a data receiving apparatus 2 according to a first embodiment of the present disclosure is applied. FIG. 3 schematically illustrates a configuration example of the data receiving apparatus 2 according to the first embodiment.

The communication system illustrated in FIG. 2 includes a data transmitting apparatus 1 and the data receiving apparatus 2. The communication system includes multiple signal lines coupling the data transmitting apparatus 1 and the data receiving apparatus 2. The multiple signal lines include a clock lane CL and multiple data lanes DL0, DL1, DL2, and DL3. The clock lane CL is a clock signal line that transmits the clock signal CLK. The multiple data signal lines DL0, DL1, DL2, and DL3 are multiple data signal lines that transmit multiple data signals D0, D1, D2, and D3, respectively. The multiple data signals D0, D1, D2, and D3 are image data, for example. It is to be noted that although FIG. 2 illustrates the example in which the four data lanes DL0, DL1, DL2, and DL3 are provided, the number of data lanes is not limited to four, and may be two, three, or five or greater, for example.

The data receiving apparatus 2 includes a DATA-DATA phase matching unit as a first phase adjustment circuit, a CLK-DATA phase matching unit 20 as a second phase adjustment circuit, and a counter 30. Further, the data receiving apparatus 2 includes multiple data input terminals 40, 41, 42, and 43 that receive the multiple data signals D0, D1, D2, and D3, respectively, and a clock input terminal 60 that receives the clock signal CLK. Further, the data receiving apparatus 2 includes multiple data output terminals 50, 51, 52, and 53 that output multiple data signals Dd0, Dd1, Dd2, and Dd3, respectively, after the phase adjustment, and a clock output terminal 70 that outputs the delay clock signal CLKd, which is the clock signal CLK having been subjected to the phase adjustment.

The DATA-DATA phase matching unit 10 includes a delay circuit 11 as a first delay circuit, a selector 12, a register 13, and a phase comparator 14. The selector 12 and the register 13 constitute a delay amount control circuit 15 that serves as a first delay amount control circuit.

The DATA-DATA phase matching unit 10 performs a phase adjustment between the multiple data signals D0, D1, D2, and D3 received via the multiple data lanes DL0, DL1, DL2, and DL3, respectively.

The delay circuit 11 outputs multiple delay data signals D0d, D1d, D2d, and D3d by delaying the multiple data signals D0, D1, D2, and D3, respectively.

The phase comparator 14 performs a phase comparison between the multiple delay data signals D0d, D1d, D2d, and D3d outputted from the delay circuit 11.

On the basis of the result of comparison by the phase comparator 14, the delay amount control circuit 15 controls the amount of delay of each of the multiple data signals D0, D1, D2, and D3 to be delayed by the delay circuit 11.

The CLK-DATA phase matching unit 20 includes a delay circuit 21 as a second delay circuit, a selector 22, a register-computing unit 23, and an edge detector 24. The selector 22 and the register-computing unit 23 constitute a delay amount control circuit 25 that serves as a second delay amount control circuit.

After the phase adjustment between the multiple data signals D0, D1, D2, and D3 is performed by the DATA-DATA phase matching unit 10, the CLK-DATA phase matching unit 20 performs a phase adjustment of the clock signal CLK received via the clock lane CL with respect to the multiple data signals D0, D1, D2, and D3.

The CLK-DATA phase matching unit 20 performs the phase adjustment of the clock signal CLK with respect to the multiple data signals D0, D1, D2, and D3 on the basis of any one of the multiple data signals after the phase adjustment is performed by the DATA-DATA phase matching unit 10 (i.e., the multiple delay data signals D0d, D1d, D2d, and D3d).

The delay circuit 21 outputs the delay clock signal CLKd obtained by delaying the clock signal CLK.

The edge detector 24 detects, on the basis of any one of the multiple delay data signals D0d, D1d, D2d, and D3d outputted from the delay circuit 11 and the delay clock signal CLKd outputted from the delay circuit 21, the rising edge Pb and the falling edge Pa of the any one of the delay data signals.

The delay amount control circuit 25 controls the amount of delay of the clock signal CLK to be delayed by the delay circuit 21 on the basis of a rising edge detection signal and a falling edge detection signal of the any one of the delay data signals outputted from the edge detector 24.

### 1.2 Operation

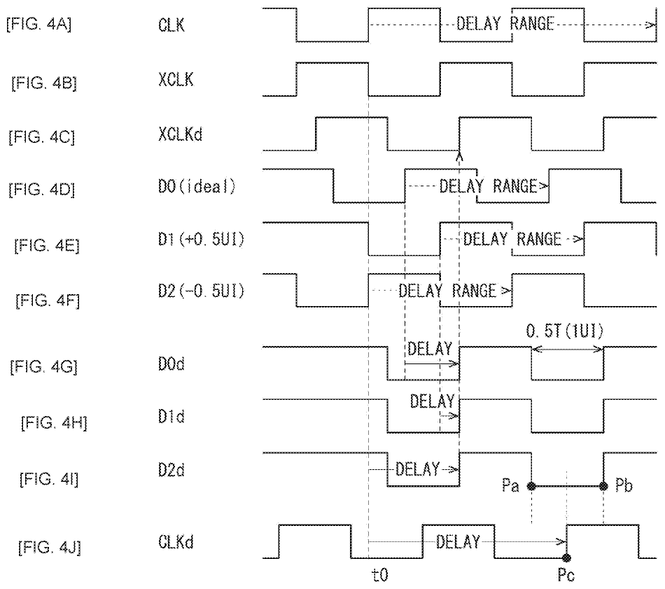

FIG. 4 is a timing chart schematically illustrating an example of an operation of the data receiving apparatus 2 according to the first embodiment. FIG. 4(A) illustrates an exemplary phase of the clock signal CLK received by the data receiving apparatus 2. FIG. 4(B) illustrates an exemplary phase of an inverted clock signal XCLK. FIG. 4(C) illustrates an exemplary phase of an inverted delay clock signal XCLKd. FIG. 4(D) illustrates an exemplary phase of the data signal DO. FIG. 4(E) illustrates an exemplary phase of the data signal DE FIG. 4(F) illustrates an exemplary phase of the data signal D2. FIG. 4(G) illustrates an exemplary phase of the delay data signal D0d. FIG. 4(H) illustrates an exemplary phase of the delay data signal D1d. FIG. 4(I) illustrates an exemplary phase of the delay data signal D2d. FIG. 4(J) illustrates an exemplary phase of the delay clock signal CLKd.

It is to be noted that only three data signals D0, D1, and D2 among the multiple data signals D0, D1, D2, and D3, and three delay data signals D0d, D1d, and D2d corresponding to the data signals D0, D1, and D2, respectively, are illustrated as representatives in FIG. 4 to simplify the description (FIGS. 4(D), 4(E), 4(F), 4(G), 4(H), and 4(I)). Further, in the example illustrated in FIG. 4, the phase of the data signal D0 is in an ideal phase condition with respect to the clock signal CLK, the phase of the data signal D1 is in a phase condition advanced by 0.5UI with respect to the clock signal CLK, and the phase of the data signal D2 is in a phase condition delayed by 0.5UI with respect to the clock signal CLK.

In the following, an operation of the data receiving apparatus 2 illustrated in FIG. 3 is described with reference to FIG. 4, as necessary.

The counter 30 outputs a counter value of the clock signal CLK (FIG. 4(A)) to the selector 12, the register 13, the selector 22, and the register-computing unit register 23.

The delay circuit 11 outputs the multiple delay data signals D0d, D1d, D2d, and D3d obtained by delaying the multiple data signals D0, D1, D2, and D3, respectively, to the phase comparator 14 (FIGS. 4(D) to 4(I)). Further, the delay circuit 11 outputs the data signals Dd0, Dd1, Dd2, and Dd3 after a final phase adjustment.

The phase comparator 14 receives the multiple delay data signals D0d, D1d, D2d, and D3d outputted from the delay circuit 11. Further, the phase comparator 14 receives the inverted delay clock signal XCLKd (FIG. 4(C)) outputted from the delay circuit 21. On the basis of the most delayed one of the multiple delay data signals D0d, D1d, D2d, and D3d, the phase comparator 14 delays the other DATA signals little by little to perform a phase comparison. If the phases match with each other, the phase comparator 14 outputs Hold signals D0_hold, D1_hold, D2_hold, and D3_hold. Here, the most delayed DATA signal is determined using the inverted delay clock signal XCLKd obtained by delaying the inverted clock signal XCLK (FIG. 4(B)).

When receiving any one (a Hold signal Dx_hold) of the multiple Hold signals D0_hold, D1_hold, D2_hold, and D3_hold from the phase comparator 14, the selector 12 selects whether to output the counter value received from the counter 30 or to output a phase retention value received from the register 13.

When receiving any one (the Hold signal Dx_hold) of the multiple Hold signals D0_hold, D1_hold, D2_hold, and D3_hold from the phase comparator 14, the register 13 stores the counter value received from the counter 30.

When receiving the output signal from the selector 12, the delay circuit 11 changes the amount of delay of each of the multiple data signals D0, D1, D2, and D3. The phase comparator 14 only has to detect either one of the rising timing and the falling timing of each of the multiple delay data signals D0d, D1d, D2d, and D3d. Thus, the amount of delay variable by the delay circuit 11 may be suppressed within a range from 0.5 cycles to 1 cycle.

Here, in a case where one cycle of each of the multiple data signals D0, D1, D2, and D3 is 1T (=2UI), it is desirable to adjust the amount of delay so that the phase shift of each of the multiple delay data signals D0d, D1d, D2d, and D3d is less than or equal to 0.075 T (=0.15UI). Further, for example, in order to allow a dynamical skew (0.175 (=0.35UI) cycles) to occur after deskewing, it is desirable to adjust an overlap of signal waveforms of any one of the delay data signals and another one of the delay data signals between the rising edge Pb and the falling edge Pa within 1UI is 0.175 cycles or greater.

It is to be noted that FIGS. 4(D) to (I) illustrate examples in which the phase shift between the multiple delay data signals D0d, D1d, and D2d is adjusted to be zero with respect to the phase condition between the multiple original data signals D0, D1, and D2. In this case, the overlap of signal waveforms of any one of the delay data signals and another one of the delay data signals between the rising edge Pb and the falling edge Pa within 1UI is 1UI.

The edge detector 24 receives any one (a Hold signal Dx_hold) of the multiple Hold signals including the Hold signals D0_hold, D1_hold, D2_hold, and D3_hold outputted from the phase comparator 14, and any one (a delay data signal Dxd_out) of the multiple delay data signals D0d, D1d, D2d, and D3d outputted from the phase comparator 14, and the delay clock signal CLKd outputted from the delay circuit 21.

The edge detector 24 operates when all of the multiple Hold signals D0_hold, D1_hold, D2_hold, and D3_hold are detected as the Hold signal Dx_hold. Further, the edge detector 24 delays the delay clock signal CLKd received from the delay circuit 21 little by little, detects the rising edge Pb and the falling edge Pa of any one delay data signal Dxd_out, and outputs edge detection signals CLK_hold corresponding to the respective edges.

When receiving the edge detection signals of the rising edge and the falling edge of the delay data signal Dxd_out as the edge detection signals CLK_hold from the edge detector 24, the selector 22 selects whether to output the counter value received from the counter 30 or to output a computed value received from the register-computing unit 23.

When receiving the rising edge detection signal and the falling edge detection signal of the any one delay data signal Dxd_out as the edge detection signals CLK_hold from the edge detector 24, the register of the register-computing unit 23 stores a counter value (Cb) at the rising timing of the any one delay data signal Dxd_out and a counter value (Ca) at the falling timing of the any one delay data signal Dxd_out as counter values received from the counter 30. The computing unit of the register-computing unit 23 calculates the expression, (Ca+Cb)/2 when receiving the counter value (Cb) at the rising timing and the counter value (Ca) at the falling timing that are stored in the register.

When receiving an output signal from the selector 22, the delay circuit 21 changes the amount of delay of the clock signal CLK. The delay clock signal CLKd having the rising edge Pc at an intermediate position between the rising edge Pb and the falling edge Pa within 1UI of the delay data signal Dxd_out is thereby generated. The amount of delay variable by the delay circuit 21 needs 1.5 to 2 cycles to enable the edge detector 24 to detect the rising edge and the falling edge of the data signal Dxd_out.

### 1.3 Effects

As described above, according to the data receiving apparatus 2 of the first embodiment, the phase adjustment of the clock signal with respect to the multiple data signals is performed after the phase adjustment between the multiple data signals is performed by the DATA-DATA phase matching unit 10. Accordingly, it is possible to perform the phase adjustment between the multiple data signals and the clock signal while reducing a circuit scale and electric consumption.

According to the data receiving apparatus 2 of the first embodiment, the CLK-DATA phase matching unit 20 may be a single system regardless of the presence of the multiple data lanes. Further, according to the data receiving apparatus 2 of the first embodiment, the phase adjustment of the clock signal, i.e., the phase adjustment of the clock signal with respect to any one of the multiple data signals is performed after the phase adjustment between the multiple data signals is performed. Thus, data signals are outputted from the multiple data lanes at the same timing. This eliminates the need for the phase adjustment of the data signals between the multiple data lanes after the phase adjustment of the clock signal. These features allow the data receiving apparatus 2 as a whole to reduce a circuit scale and electric consumption.

It is to be noted that the effects described herein are mere examples and should not be limitative, and other effects may be provided. The same applies to the other embodiments described below.

### 2. Second Embodiment

Next, a data receiving apparatus according to a second embodiment of the present disclosure is described. It is to be noted that components that are the same as the components in the data receiving apparatus according to the first embodiment are hereinafter denoted by the same reference numerals and the description thereof is omitted as appropriate.

### 2.1 Configuration

FIG. 5 schematically illustrates a configuration example of a data receiving apparatus 2 according to the second embodiment of the present disclosure.

The data receiving apparatus 2 according to the second embodiment includes a DATA-DATA phase matching unit 10A as a first phase adjustment circuit, and a CLK-DATA phase matching unit 20A as a second phase adjustment circuit.

The DATA-DATA phase matching unit 10A includes a phase comparator 14A in place of the phase comparator 14 of the first embodiment.

The CLK-DATA phase matching unit 20A includes an edge detector 24A in place of the edge detector 24 of the first embodiment.

### 2.2 Operation

FIG. 6 is a timing chart schematically illustrating an exemplary operation of the data receiving apparatus 2 according to the second embodiment. FIG. 6(A) illustrates an exemplary phase of a data signal DO. FIG. 6(B) illustrates an exemplary phase of a data signal D1. FIG. 6(C) illustrates an exemplary phase of a data signal D2. FIG. 6(D) illustrates an exemplary phase of a delay data signal D0d. FIG. 6(E) illustrates an exemplary phase of a delay data signal D1d. FIG. 6(F) illustrates an exemplary phase of a delay data signal D2d. FIG. 6(G) illustrates an exemplary phase of an NAND signal Dxd_nand. FIG. 6(H) illustrates an exemplary phase of a clock signal CLK received by the data receiving apparatus 2. FIG. 6(I) illustrates an exemplary phase of a delay clock signal CLKd.

In FIG. 6, only three data signals D0, D1, and D2 among the multiple data signals D0, D1, D2, and D3, and three delay data signals D0d, D1d, and D2d corresponding to the data signals D0, D1, and D2, respectively, are illustrated as representatives in FIG. 6 to simplify the description (FIGS. 6(A), 6(B), 6(C), 6(D), 6(F), and 6(G)). Further, in the example illustrated in FIG. 6, the phase of the data signal D0 is in an ideal phase condition with respect to the clock signal CLK, the phase of the data signal D1 is in a phase condition advanced by 0.5UI with respect to the clock signal CLK, and the phase of the data signal D2 is in a phase condition delayed by 0.5UI with respect to the clock signal CLK.

The phase comparator 14A receives the multiple delay data signals D0d, D1d, D2d, and D3d outputted from the delay circuit 11. The phase comparator 14A performs a phase comparison by delaying each of the multiple delay data signals D0d, D1d, D2d, and D3d little by little and outputs any one (a Hold signal Dx_hold) of the delay data signals. Further, the phase comparator 14A outputs the NAND signal Dxd_nand obtained by conducting the NAND on all of the multiple delay data signals D0d, D1d, D2d, and D3d (FIGS. 6(D) to 6(G)).

When receiving the output signal from the selector 12, the delay circuit 11 changes the amount of delay of each of the multiple data signals D0, D1, D2, and D3. The phase comparator 14A only has to detect either one of the rising timing and the falling timing of each of the multiple delay data signals D0d, D1d, D2d, and D3d. Thus, the amount of delay variable by the delay circuit 11 may be suppressed within a range from 0.5 cycles to 1 cycle.

As described in the first embodiment, in a case where one cycle of each of the multiple data signals D0, D1, D2, and D3 is 1T (=2UI), it is desirable to adjust the amount of delay so that the phase shift of each of the multiple delay data signals D0d, D1d, D2d, and D3d (see FIGS. 6(D) to 6(F)) is less than or equal to 0.075T (=0.15UI). Further, for example, in order to allow a dynamical skew (0.175 (=0.35UI) cycles) to occur after deskewing, it is desirable to adjust an overlap of signal waveforms any one of the delay data signals and another one of the delay data signals between the rising edges Pb and the falling edges Pa within 1UI is 0.175 cycles or greater.

The CLK-DATA phase matching unit 20A performs the phase adjustment of the clock signal CLK with respect to the multiple data signals D0, D1, D2, and D3 on the basis of a signal (i.e., the NAND signal Dxd_nand) obtained after a logical operation using each of the multiple data signals after the phase adjustment is performed by the DATA-DATA phase matching unit 10A (i.e., the multiple delay data signals D0d, D1d, D2d, and D3d).

On the basis of the signal (i.e., the NAND signal Dxd_nand) obtained after the logical operation using the multiple delay data signals D0d, D1 d, D2d, and D3d outputted from the delay circuit 11 and the delay clock signal CLKd outputted from the delay circuit 21, the edge detector 24A detects a rising edge Pnb and a falling edge Pna of the NAND signal Dxd_nand that is the signal obtained after the logical operation (see FIG. 6(G)).

The edge detector 24A receives any one (the Hold signal Dx_hold) of the multiple Hold signals D0_hold, D1_hold, D2_hold, and D3_hold outputted from the phase comparator 14A, the NAND signal Dxd_nand that is a signal outputted from the phase comparator 14 after the logical operation, and the delay clock signal CLKd outputted from the delay circuit 21.

The edge detector 24A detects the rising edge Pnb and the falling edge Pna of the NAND signal Dxd_nand, and outputs edge detection signals CLK_hold corresponding to the respective edges.

When receiving the rising edge detection signal and the falling edge detection signal of the NAND signal Dxd_nand as the edge detection signals CLK_hold from the edge detector 24A, the selector 22 selects whether to output the counter value received from the counter 30 or to output a computed value received from the register-computing unit 23.

When receiving the rising edge detection signal and the falling edge detection signal of the NAND signal Dxd_nand as the edge detection signals CLK_hold from the edge detector 24A, the register of the register-computing unit 23 stores a counter value (Cb) at the rising timing of the NAND signal Dxd_nand and a counter value (Ca) at the falling timing of the NAND signal Dxd_nand as counter values received from the counter 30. The register-computing unit 23 calculates the expression, (Ca+Cb)/2 when receiving the counter value (Cb) at the rising timing and the counter value (Ca) at the falling timing that are stored in the register.

The delay amount control circuit 25 controls the amount of delay of the clock signal CLK to be delayed by the delay circuit 21 on the basis of the rising edge detection signal and the falling edge detection signal of the signal obtained after the logical operation and outputted from the edge detector 24A (i.e., the NAND signal Dxd_nand).

When receiving an output signal from the selector 22, the delay circuit 21 changes the amount of delay of the clock signal CLK. The delay clock signal CLKd having the rising edge Pc at an intermediate position between the rising edge Pnb and the falling edge Pna of the NAND signal Dxd_nand is thereby generated (see SIGs. 6(G) and 6(I)). As a result of this, the delay clock signal CLKd is generated which has the rising edge Pc at an intermediate position between the rising edge Pb and the falling edge Pa within 1UI of each of the multiple delay data signals D0d, D1d, D2d, and D3d.

### 2.3 Effects

Also in the data receiving apparatus 2 according to the second embodiment, the CLK-DATA phase matching unit 20A may be a single system regardless of the presence of the multiple data lanes. Further, according to the data receiving apparatus 2 of the second embodiment, the phase adjustment of the clock signal, i.e., the phase adjustment between the clock signal and the signal obtained after the logical operation using each of the multiple delay data signals is performed after the phase adjustment between the multiple data signals is performed. Thus, data signals are outputted from the multiple data lanes at the same timing. This eliminates the need for the phase adjustment of the data signals between the multiple data lanes after the phase adjustment of the clock signal. These features allow the data receiving apparatus 2 as a whole to reduce a circuit scale and electric consumption.

Other configurations, operations, and effects may be substantially the same as those of the first embodiment described above.

### 3. Other Embodiments

The technology of the present disclosure is not limited to the description of each of the embodiments described above, and various modification may be made.

For example, the technology may have the following configurations. According to the following configurations of the technology described below, the phase adjustment of the clock signal with respect to the multiple data signals is performed after the phase adjustment between the multiple data signals is performed by the first phase adjustment circuit. Accordingly, it is possible to perform the phase adjustment between the multiple data signals and the clock signal while reducing a circuit scale and electric consumption.
(1) A data receiving apparatus including:
   a first phase adjustment circuit that performs a phase adjustment between multiple data signals received via multiple data signal lines; and
   a second phase adjustment circuit that performs a phase adjustment of a clock signal received via a clock signal line with respect to the multiple data signals after the phase adjustment between the multiple data signals is performed by the first phase adjustment circuit.
(2) The data receiving apparatus according to (1) described above, in which the second phase adjustment circuit performs the phase adjustment of the clock signal with respect to the multiple data signals on the basis of any one of the multiple data signals after the phase adjustment is performed by the first phase adjustment circuit.
(3) The data receiving apparatus according to (1) described above, in which the second phase adjustment circuit performs the phase adjustment of the clock signal with respect to the multiple data signals on the basis of a signal obtained after a logical operation using each of the multiple data signals after the phase adjustment is performed by the first phase adjustment circuit.
(4) The data receiving apparatus according to any one of (1) to (3) described above, in which
   the first phase adjustment circuit includes
   a first delay circuit that outputs multiple delay data signals by delaying each of the multiple data signals, and
   a phase comparator that performs a phase comparison between the multiple delay data signals outputted from the first delay circuit.
(5) The data receiving apparatus according to (4) described above, in which
   the first phase adjustment circuit further includes
   a first delay amount control circuit that controls an amount of delay of each of the multiple data signals to be delayed by the first delay circuit on the basis of a signal based on a result of the comparison by the phase comparator.
(6) The data receiving apparatus according to (4) or (5) described above, in which
   the second phase adjustment circuit includes
   a second delay circuit that outputs a delay clock signal obtained by delaying the clock signal, and
   an edge detector that detects, on the basis of any one of the multiple delay data signals outputted from the first delay circuit and the delay clock signal outputted from the second delay circuit, a rising edge and a falling edge of the any one delay data signal.
(7) The data receiving apparatus according to (6) described above, in which
the second phase adjustment circuit further includes
a second delay amount control circuit that controls an amount of delay of the clock signal to be delayed by the second delay circuit on the basis of a rising edge detection signal and a falling edge detection signal of the any one delay data signal outputted from the edge detector.
(8) The data receiving apparatus according to (4) or (5) described above, in which
   the second phase adjustment circuit includes
   a second delay circuit that outputs a delay clock signal obtained by delaying the clock signal, and
   an edge detector that detects, on the basis of a signal obtained after a logical operation using the multiple delay data signals outputted from the first delay circuit and the delay clock signal outputted from the second delay circuit, a rising edge and a falling edge of the signal obtained after the logical operation.
(9) The data receiving apparatus according to (8) described above, in which
   the second phase adjustment circuit further includes
   a second delay amount control circuit that controls an amount of delay of the clock signal to be delayed by the second delay circuit on the basis of a rising edge detection signal and a falling edge detection signal of the signal obtained after the logical operation and outputted from the edge detector.

This application claims the benefit of Japanese Priority Patent Application JP2020-190021 filed with the Japan Patent Office on Nov. 16, 2020, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A data receiving apparatus comprising:
a first phase adjustment circuit that performs a phase adjustment between multiple data signals received via multiple data signal lines; and
a second phase adjustment circuit that performs a phase adjustment of a clock signal received via a clock signal line with respect to the multiple data signals after the phase adjustment between the multiple data signals is performed by the first phase adjustment circuit.

2. The data receiving apparatus according to claim 1, wherein
the second phase adjustment circuit performs the phase adjustment of the clock signal with respect to the multiple data signals on a basis of any one of the multiple data signals after the phase adjustment is performed by the first phase adjustment circuit.

3. The data receiving apparatus according to claim 1, wherein
the second phase adjustment circuit performs the phase adjustment of the clock signal with respect to the multiple data signals on a basis of a signal obtained after a logical operation using each of the multiple data signals after the phase adjustment is performed by the first phase adjustment circuit.

4. The data receiving apparatus according to claim 1, wherein
the first phase adjustment circuit includes
a first delay circuit that outputs multiple delay data signals by delaying each of the multiple data signals, and
a phase comparator that performs a phase comparison between the multiple delay data signals outputted from the first delay circuit.

5. The data receiving apparatus according to claim 4, wherein
the first phase adjustment circuit further includes
a first delay amount control circuit that controls an amount of delay of each of the multiple data signals to be delayed by the first delay circuit on a basis of a signal based on a result of the comparison by the phase comparator.

6. The data receiving apparatus according to claim 4, wherein
the second phase adjustment circuit includes
a second delay circuit that outputs a delay clock signal obtained by delaying the clock signal, and
an edge detector that detects, on a basis of any one of the multiple delay data signals outputted from the first delay circuit and the delay clock signal outputted from the second delay circuit, a rising edge and a falling edge of the any one delay data signal.

7. The data receiving apparatus according to claim 6, wherein
the second phase adjustment circuit further includes
a second delay amount control circuit that controls an amount of delay of the clock signal to be delayed by the second delay circuit on a basis of a rising edge detection signal and a falling edge detection signal of the any one delay data signal outputted from the edge detector.

8. The data receiving apparatus according to claim 4, wherein
the second phase adjustment circuit includes
a second delay circuit that outputs a delay clock signal obtained by delaying the clock signal, and
an edge detector that detects, on a basis of a signal obtained after a logical operation using the multiple delay data signals outputted from the first delay circuit and the delay clock signal outputted from the second delay circuit, a rising edge and a falling edge of the signal obtained after the logical operation.

9. The data receiving apparatus according to claim 8, wherein
the second phase adjustment circuit further includes
a second delay amount control circuit that controls an amount of delay of the clock signal to be delayed by the second delay circuit on a basis of a rising edge detection signal and a falling edge detection signal of the signal obtained after the logical operation and outputted from the edge detector.
